(19) United States
(12) Patent Application Publication
(10) Pub. No.: US 2014/0251662 A1
(43) Pub. Date: Sep. 11, 2014

(54) OPTICALLY CLEAR CONDUCTIVE ADHESIVE AND ARTICLES THEREFROM

(71) Applicant: 3M INNOVATIVE PROPERTIES COMPANY, St. Paul, MN (US)

(72) Inventors: Nelson T. Rotto, Woodbury, MN (US); Robert C. Fitzer, North Oaks, MN (US); John D. Le, Woodbury, MN (US)

(73) Assignee: 3MM Innovative Properties Company, St Paul, MN (US)

(21) Appl. No.: 14/237,996

(22) PCT Filed: Jul. 30, 2012
(86) PCT No.: PCT/US12/48769

§ 371 Date: May 23, 2014

Related U.S. Application Data
(60) Provisional application No. 61/522,969, filed on Aug. 12, 2011.

(51) Int. Cl. H05K 1/02; H05K 1/03

(52) U.S. Cl. CPC H05K 1/0274; H05K 1/03; H05K 1/0216; Y10S 977/932; B82Y 99/00
USPC 174/253; 174/255; 977/932

(57) ABSTRACT

The present invention provides an electrically conductive, optically clear adhesive including an optically clear adhesive layer and an interconnected, electrically conductive network layer positioned over the optically clear adhesive layer. The electrically conductive, optically clear adhesive has a conductivity of between about 0.5 and about 1000 ohm/sq, haze of less than about 10%, and a transmittance of at least about 80%.

### CROSS REFERENCE TO RELATED APPLICATIONS

This application claims priority from U.S. Provisional Application Ser. No. 61/522,969, filed Aug. 12, 2011, the disclosure of which is incorporated by reference in its/their entirety herein.

### TECHNICAL FIELD

The present invention is related generally to optically clear adhesives. In particular, the present invention is related to electrically conductive, optically clear adhesives that can be used as transparent, electrical conductors.

### BACKGROUND

Optically clear adhesives are used extensively in electronic displays to adhere various components and layers of an electronic display together. Major components of an electronic display include, for example: a glass cover, a touch screen, an anti-reflective layer, an air gap, and a liquid crystal display (LCD). In electronic displays that include a LCD, the LCD may be electrically noisy and interfere with other components, such as the touch screen, which is susceptible to the electric field created by the LCD. One solution has been to position the touch sensor away from the LCD by introducing an air gap or a thick layer of optically clear adhesive (OCA). Another solution has been to position a transparent, electromagnetic interference (EMI) layer between the LCD and the touch screen to prevent unwanted electromagnetic interference with the touch screen. However, both of these solutions increase the overall thickness of the electronic display and optical penalties. Because consumers are demanding increasingly thinner electronic displays, it would be desirable to provide an electronic display having means to prevent unwanted electromagnetic interference without the addition of another layer.

### SUMMARY

In one embodiment, the present invention is an electrically conductive, optically clear adhesive. The electrically conductive, optically clear adhesive includes an optically clear adhesive layer and an interconnected, electrically conductive network layer positioned over the optically clear adhesive layer. The electrically conductive, optically clear adhesive has a conductivity of between about 0.5 and about 1000 Ohm/square, haze of less than about 10%, and a transmittance of at least about 80%.

In another embodiment, the present invention is an electrically conductive, optically clear adhesive including an optically clear adhesive layer, a conductive nanowire network layer positioned over the optically clear adhesive layer, and an optically clear adhesive layer topcoat positioned over the conductive nanowire network layer. The conductive nanowire network layer helps control electromagnetic interference.

### BRIEF DESCRIPTION OF DRAWINGS

FIG. 1 is a cross-sectional view of a first embodiment of an electrically conductive optically clear adhesive of the present invention.

FIG. 2 is a cross-sectional view of the first embodiment of the electrically conductive optically clear adhesive of FIG. 1 including a perimeter of electrically conductive ink and a conductive tab.

FIG. 3 is an X/Y plane view of a perimeter and a connection tab of electrically conductive ink.

FIG. 4 is a cross-sectional view of a second embodiment of an electrically conductive optically clear adhesive of the present invention.

FIG. 5 is a cross-sectional view of the second embodiment of the electrically conductive optically clear adhesive of FIG. 4 including a perimeter of electrically conductive ink and a conductive tab.

FIG. 6 is a cross-sectional view of the first embodiment of the electrically conductive optically clear adhesive of the present invention positioned within an electronic display.

### DETAILED DESCRIPTION

FIG. 1 shows a cross-sectional view of an electrically conductive optically clear adhesive (COCA) 10 of the present invention and includes an optically clear adhesive (OCA) layer 12 coated with an interconnected, electrically conductive network layer 14. An optically clear adhesive topcoat 16 may optionally be coated or laminated over the interconnected, electrically conductive network layer 14 as a topcoat to form a multi-layered structure of OCA—interconnected, electrically conductive network coating—OCA. A first releasing substrate 18 is positioned adjacent the optically clear adhesive layer 12 and a second releasing substrate 20 is positioned adjacent the optically clear adhesive topcoat 16. This multi-layered structure can then be used in an electronic display apparatus to provide both adhesion of two components of the electronic display, as well as an electromagnetic shield which prevents two components of the electronic display from interfering with each other.

As used in this specification, the term “optically clear” refers to an adhesive or article that has a high light transmittance over at least a portion of the visible light spectrum (about 400 to about 700 nanometers), and that exhibits low haze. Both the luminous transmission and the haze can be determined using, for example, the method of ASTM-D 1003-95.

The COCA 10 has a low enough haze level sufficient to allow a user to discern any images or writing. In one embodiment, the COCA 10 has about 10% haze or less, particularly about 5% haze or less, and more particularly about 2% haze or less.

The COCA 10 has a transmittance level high enough to allow visibility to the user. In one embodiment, the COCA 10 has greater than about 80% transmittance, particularly greater than about 85% transmittance, and more particularly greater than about 88% transmittance.

In one embodiment, the COCA 10 is birefringence-free.

In one embodiment, the thickness of the COCA 10 is least about 1 micron, at least about 5 microns, at least about 10 microns, at least about 15 microns, or at least 20 microns. The thickness is often no greater than about 500 microns, no greater than about 300 microns, no greater than about 150 microns, or no greater than about 125 microns. For example, the thickness can be about 1 to about 200 microns, about 5 to about 100 microns, about 10 to about 50 microns, about 20 to about 50 microns, or about 1 to about 15 micrometers.

### Optically Clear Adhesive

The OCA layer 12, or the reactive mixture which upon polymerization forms the adhesive, may be coated onto a surface to form the adhesive layer. The term “adhesive” as used herein refers to polymeric compositions useful to adhere together two adherends. A wide variety of adhesives are suitable for forming the adhesive layer or adhesive topcoat of this disclosure. Suitable adhesives include, for example, heat activated adhesive and pressure sensitive adhesives. Especially suitable are pressure sensitive adhesives. The adhesive used is chosen to have properties suitable for the desired application. In some embodiments, the OCA layers 12, 16 may be stretch release adhesives.

Heat activated adhesives are non-tacky at room temperature but become tacky and capable of bonding to a substrate at elevated temperatures. These adhesives usually have a Tg or melting point (Tm) above room temperature. When the temperature is elevated above the Tg or Tm, the storage modulus usually decreases and the adhesive become tacky.

Pressure sensitive adhesive compositions are well known to those of ordinary skill in the art to possess at room temperature properties including the following: (1) aggressive and permanent tack, (2) adherence with no more than finger pressure, (3) sufficient ability to hold onto an adherend, and (4) sufficient cohesive strength to be cleanly removable from the adherend. Materials that have been found to function well as PSAs are polymers designed and formulated to exhibit the requisite viscoelastic properties resulting in a desired balance of tack, peel adhesion, and shear holding power. Obtaining the proper balance of properties is not a simple process.

As mentioned above, an optional OCA topcoat 16 may be coated onto the interconnected, electrically conductive network layer 14. The OCA topcoat 16 may be coated onto the interconnected, electrically conductive network layer 14 in order to improve the tackiness of the interconnected, electrically conductive network layer 14. However, if the interconnected, electrically conductive network layer 14 is an adhesive, the OCA topcoat 16 is not needed. If an OCA topcoat 16 is incorporated into the adhesive, it may be thick or thin, insulated or not insulated, uniform or discontinuous, and phase uniform or phase separated.

The OCA layer 12 and the OCA topcoat 16 may either be the same OCA or different OCAs. The OCA layer 12 and the OCA topcoat 16 may be different in order to ensure compatibility with adjacent substrates. In one embodiment, the OCA layer 12 and the OCA topcoat 16 has a thickness of between about 1 nanometer (nm) to about 500 microns.

Optically clear adhesives suitable for use in the present disclosure include, for example, those based on natural rubbers, synthetic rubbers, styrene block copolymers, (meth)acrylic block copolymers, polyvinyl ethers, polyolefins, and poly(meth)acrylates. The terms (meth)acrylate and (meth)acrylic include both acrylates and methacrylates.

One particularly suitable class of optically clear adhesives are (meth)acrylate-based adhesives and may comprise either an acidic or basic copolymer. In some embodiments the (meth)acrylate-based adhesive is an acidic copolymer. The acidic copolymer may contain one or more acidic monomer types. Generally, as the proportion of acidic monomers used in preparing the acidic copolymer increases, cohesive strength of the resulting adhesive increases. The proportion of acidic monomers is usually adjusted depending on the proportion of acidic copolymer present in the adhesive blends of the present disclosure.

In some embodiments, the adhesive is an optically clear pressure sensitive adhesive. To achieve pressure sensitive adhesive characteristics, the corresponding copolymer can be tailored to have a resultant glass transition temperature (Tg) of less than about 0° C. Particularly suitable pressure sensitive adhesive copolymers are (meth)acrylate copolymers. Such copolymers typically are derived from monomers comprising about 40% by weight to about 98% by weight, often at least 70% by weight, or at least 85% by weight, or even about 90% by weight, of at least one alkyl (meth)acrylate monomer that, as a homopolymer, has a Tg of less than about 0° C.

Examples of such alkyl (meth)acrylate monomers are those in which the alkyl groups comprise from about 4 carbon atoms to about 12 carbon atoms and include, but are not limited to, n-butyl acrylate, 2-ethylhexyl acrylate, isooctyl acrylate, isononyl acrylate, isodecyl acrylate, and mixtures thereof. Optionally, other vinyl monomers and alkyl (meth)acrylate monomers which, as homopolymers, have a Tg greater than 0° C., such as methyl acrylate, methyl methacrylate, isobornyl acrylate, vinyl acetate, styrene, and the like, may be utilized in conjunction with one or more of the low Tg alkyl (meth)acrylate monomers and copolymerizable basic or acidic monomers, provided that the Tg of the resultant (meth)acrylate copolymer is less than about 0° C.

In some embodiments, it is desirable to use (meth)acrylate monomers that are free of alkoxy groups. Alkoxy groups are understood by those skilled in the art.

When used, basic (meth)acrylate copolymers useful as the pressure sensitive adhesive matrix typically are derived from basic monomers comprising about 2% by weight to about 50% by weight, or about 5% by weight to about 30% by weight, of a copolymerizable basic monomer. Exemplary basic monomers include N,N-dimethylaminopropyl methacrylamide (DMAPMAm); N,N-diethylaminopropyl methacrylamide (DEAPMAm); N,N-dimethylaminoethyl acrylate (DMAEA); N,N-diethylaminoethyl acrylate (DEAEA); N,N-dimethylaminopropyl acrylate (DMAPA); N,N-diethylaminopropyl acrylate (DEAPA); N,N-dimethylaminoethyl methacrylate (DMAEMA); N,N-diethylaminoethyl methacrylate (DEAEMA); N,N-dimethylaminoethyl acrylamide (DMAEAm); N,N-dimethylaminoethyl methacrylamide (DMAEMAm); N,N-diethylaminoethyl acrylamide (DEAEAm); N,N-diethylaminoethyl methacrylamide (DEAEMAm); N,N-dimethylaminoethyl vinyl ether (DMAEVE); N,N-diethylaminoethyl vinyl ether (DEAEVE); and mixtures thereof. Other useful basic monomers include vinylpyridine, vinylimidazole, tertiary amino-functionalized styrene (e.g., 4-(N,N-dimethylamino)-styrene (DMAS), 4-(N,N-diethylamino)-styrene (DEAS)), N-vinylpyrrolidone, N-vinylcaprolactam, acrylonitrile, N-vinylformamide, (meth)acrylamide, and mixtures thereof.

When used to form the pressure sensitive adhesive matrix, acidic (meth)acrylate copolymers typically are derived from acidic monomers comprising about 2% by weight to about 30% by weight, or about 2% by weight to about 15% by weight, of a copolymerizable acidic monomer. Useful acidic monomers include, but are not limited to, those selected from ethylenically unsaturated carboxylic acids, ethylenically unsaturated sulfonic acids, ethylenically unsaturated phosphonic acids, and mixtures thereof. Examples of such compounds include those selected from acrylic acid, methacrylic acid, itaconic acid, fumaric acid, crotonic acid, citraconic acid, maleic acid, oleic acid, beta-carboxyethyl acrylate, 2-sulfoethyl methacrylate, styrenesulfonic acid, 2-acrylamido-2-methylpropanesulfonic acid, vinylphosphonic acid, and the like, and mixtures thereof. Due to their availability, typically ethylenically unsaturated carboxylic acids are used.

In certain embodiments, the poly(meth)acrylic pressure sensitive adhesive matrix is derived from between about 1 and about 20 weight percent of acrylic acid and between about 99 and about 80 weight percent of at least one of isooctyl acrylate, 2-ethylhexyl acrylate or n-butyl acrylate. In some embodiments, the pressure sensitive adhesive matrix is derived from between about 2 and about 10 weight percent acrylic acid and between about 90 and about 98 weight percent of at least one of isooctyl acrylate, 2-ethylhexyl acrylate or n-butyl acrylate.

Another useful class of optically clear (meth)acrylate-based adhesives are those which are (meth)acrylic block copolymers. Such copolymers may contain only (meth)acrylate monomers or may contain other co-monomers such as styrenes. Examples of such adhesives are described, for example in U.S. Pat. No. 7,255,920 (Everaerts et al.).

The adhesive may be inherently tacky. If desired, tackifiers may be added to a base material to form a pressure sensitive adhesive. Useful tackifiers include, for example, rosin ester resins, aromatic hydrocarbon resins, aliphatic hydrocarbon resins, and terpene resins. Other materials can be added for special purposes, including, for example, oils, plasticizers, antioxidants, ultraviolet (“UV”) stabilizers, hydrogenated butyl rubber, pigments, curing agents, polymer additives, thickening agents, chain transfer agents and other additives provided that they do not significantly reduce the optical clarity of the pressure sensitive adhesive.

In some embodiments it is desirable for the adhesive composition to contain a crosslinking agent. The choice of crosslinking agent depends upon the nature of polymer or copolymer which one wishes to crosslink. The crosslinking agent is used in an effective amount, by which is meant an amount that is sufficient to cause crosslinking of the pressure sensitive adhesive to provide adequate cohesive strength to produce the desired final adhesion properties to the substrate of interest. Generally, when used, the crosslinking agent is used in an amount of about 0.1 part to about 10 parts by weight, based on the total amount of monomers and/or polymers of the adhesive composition.

One class of useful crosslinking agents include multifunctional (meth)acrylate species. Multifunctional (meth)acrylates include tri(meth)acrylates and di(meth)acrylates (that is, compounds comprising three or two (meth)acrylate groups). Typically di(meth)acrylate crosslinkers (that is, compounds comprising two (meth)acrylate groups) are used. Useful di(meth)acrylates include, for example, ethylene glycol di(meth)acrylate, diethylene glycol di(meth)acrylate, triethylene glycol di(meth)acrylate, tetraethylene glycol di(meth)acrylate, 1,4-butanediol di(meth)acrylate, 1,6-hexanediol di(meth)acrylate, alkoxylated 1,6-hexanediol diacrylates, tripropylene glycol diacrylate, dipropylene glycol diacrylate, cyclohexane dimethanol di(meth)acrylate, alkoxylated cyclohexane dimethanol diacrylates, ethoxylated bisphenol A di(meth)acrylates, neopentyl glycol diacrylate, polyethylene glycol di(meth)acrylates, polypropylene glycol di(meth)acrylates, and urethane di(meth)acrylates. Useful tri(meth)acrylates include, for example, trimethylolpropane tri(meth)acrylate, propoxylated trimethylolpropane triacrylates, ethoxylated trimethylolpropane triacrylates, tris(2-hydroxy ethyl)isocyanurate triacrylate, and pentaerythritol triacrylate.

Another useful class of crosslinking agents contain functionality which is reactive with carboxylic acid groups on the acrylic copolymer. Examples of such crosslinkers include multifunctional aziridine, isocyanate, epoxy, and carbodiimide compounds. Examples of aziridine-type crosslinkers include, for example 1,4-bis(ethyleneiminocarbonylamino)benzene, 4,4′-bis(ethyleneiminocarbonylamino)diphenylmethane, 1,8-bis(ethyleneiminocarbonylamino)octane, and 1,1′-(1,3-phenylene dicarbonyl)-bis-(2-methylaziridine). The aziridine crosslinker 1,1′-(1,3-phenylene dicarbonyl)-bis-(2-methylaziridine) (CAS No. 7652-64-4), referred to herein as “Bisamide” is particularly useful. Common polyfunctional isocyanate crosslinkers include, for example, trimethylolpropane toluene diisocyanate, tolylene diisocyanate, and hexamethylene diisocyanate.

OCAs are used in consumer mobile devices for enhancing the user's view, aesthetics and appearance of the device, as well as for touch sensor bonding. Design considerations and requirements for OCAs include excellent adhesion and clarity by eliminating yellowing that can occur to various types of transparent substrates. OCAs also enable high speed lamination required for mass production in the electronics industry. Other features include optical clarity, >99% light transmission, <1% haze level, birefringence-free, without film carrier, refractive index, designed and manufactured to eliminate common adhesive visual defects including bubbles, dirt and gels, durable adhesion, high cohesive and peel strengths for reliably bonding most transparent film substrates to glass, high temperature, humidity, and UV light resistance, long-term durability without yellowing, delaminating, or degrading. Examples of commercially suitable and available OCAs include, but are not limited to 3M™ Optically Clear Adhesive and 3M™ Contrast Enhancement Film, available from 3M Company, St. Paul, Minn.

Designing an OCA component for a COCA may also include possible ranges of adhesive options for various performance criteria and purposes. The OCA can also feature a thermally conductive adhesive, removable adhesive, high or low tack adhesive, pressure sensitive adhesive, heat or light or moisture curing adhesive, epoxy or acrylic or silicon or rubber or urethane based adhesive, thermosetting adhesive, self-wetting adhesive, structured adhesive, stretch release adhesive, electrically conductive adhesive, high or low dielectric constant adhesive, high or low refractive index adhesive, air-bleed adhesive, hot melt adhesive, etc. For example, for a COCA laminated on a OLED display, it may be desirable for the adhesive to be thermally conductive to allow better heat dissipation from the OLED device. The specialized adhesive may require certain formulations and processes which are known to those having ordinary skill in the art. A book by Alphonsus V. Pocius titled: Adhesion and Adhesives Technology: An Introduction (2002) is good introduction to the adhesive technology.

### Transparent, Interconnected, Electrically Conductive Network Layer

The interconnected, electrically conductive network layer 14 is transparent and functions as an electromagnetic interference (EMI) shield such that the COCA 10 has EMI shielding properties. This allows the transparent, interconnected, electrically conductive network layer 14 to be applied for a wide range of applications. Exemplary applications include, but are not limited to: NIR control windows, low-emissivity windows, transparent electrodes for solar cells, display panels, electrochromic display/windows, clear touch sensors, transparent electromagnetic shields, transparent electrical circuitries, and transparent antenna.

The interconnected, electrically conductive network layer 14 can include nanowires, mesh-like or pattern-wise conductive networks or open/discontinuous conductive coatings. The term “nanowire” as used herein (unless an individual context specifically implies otherwise) will generally refer to wires and groups of wires that while potentially varied in specific geometric shape have an effective, or average, diameter that can be measured on a nanoscale (i.e., less than about 100 nanometers). The transparent, interconnected, electrically conductive network layer 14 may include the nanowires, mesh-like or pattern-wise conductive networks or open/discontinuous conductive coating in liquid media. The liquid media may comprise, for example water, an alcohol such as methanol, ethanol, isopropanol, a ketone such as acetone or methyl ethyl ketone, an ester such as ethyl acetate, or a combination thereof. Surfactants may also be included to modify the wetting properties of the liquid media.

Optical design may be needed to target optical transparency performance. Such design may be a stack design of a multilayer metal/dielectric layer, or a pattern, mesh configuration or open structure configuration to optimize optical transparency at the balance of electrical performance. Opaque materials or less transparent materials can be highly transparent when in a mesh configuration, network, or open configuration. Transparent conductor designs can utilize the concept of pattern, mesh configuration or open structure configuration to optimize optical transparency at the balance of electrical performance or other performance criteria. One important parameter is pattern visibility. Design and discussion for low pattern visibility patterned transparent conductor can be found in PCT International Publication No. WO 2010099132.

The transparent, interconnected, electrically conductive network layer 14 can be prepared using a wide variety of materials and methods. Exemplary materials include, but are not limited to: semiconducting oxides of tin, indium, zinc, and cadmium; silver, gold, and titanium; conductive polymers; and conductive nanostructure materials such as carbon nanotubes, graphene, metal nanowires, and semiconductor nanowires. In one embodiment, the interconnected, electrically conductive network layer 14 includes silver nanowires such as those commercially available from Cambrios Technologies Corporation, Sunnyvale, Calif. or Seashell Technology LLC, Scotts Valley, Calif.

Processes capable of fabricating the transparent, interconnected, electrically conductive network layer can range from physical methods such as sputtering and evaporation, chemical methods such as sol gel and electroplating, solution methods such as nanowire/nanotube solution coating, and mechanical methods such as graphene bluffing.

More details on depositing a transparent, interconnected, electrically conductive network layer using physical deposition can be found in PCT International Publication Nos. WO 2011/017039, WO 2009/149032, WO 2009/05860, and WO 00/26973. Another method to mechanically deposit the transparent, interconnected, electrically conductive network layer is illustrated in U.S. Pat. No. 6,511,701, and PCT International Publication No. WO 2001/085361. This method can be used to deposit carbon nanotubes, metal nanowires, graphene, and other conductive materials onto the supporting web.

Solution-process based conductive coatings may provide a potential low cost manufacturing approach without significant capital investment. Solution-processed metal nanowire mesh-like conductive coatings are capable of achieving at least equivalent electrical and optical performance compared to conductive oxides, and may be more durable to bending and folding. Nanowire and nanostructure based dispersions can be coated by various coating methods including, but not limited to: printing, screen printing, microcontact printing, spray coating, dip coating, spin coating, and roll-to-roll coating. Roll-to-roll coating methods are preferable and include, but are not limited to: knife coating, flexo coating, curtain coating, Gravure coating, and slot die coating.

The dispersion can also be formulated to add functionality to the transparent, interconnected, electrically conductive network layer. Exemplary additives include, but are not limited to: chemical dyes, surfactants, binders, adhesives, monomers, anti-corrosion agents, cross-linkers, curatives, etc. Additional treatments to such nanostructure-based conductive coatings may be necessary to provide stability and reliability and to enhance performance. Annealing treatments including rapid thermal annealing, or calendaring treatment may also improve the conductivity of the coating. Anti-corrosion treatments including barrier coating, encapsulation, protection layer coating, chemical passivation may improve reliability of the transparent, interconnected, electrically conductive network layer.

The transparent, interconnected, electrically conductive network layer 14 can be applied by being coated, laid on, or directly applied to the OCA later 12 or OCA topcoat 16. The transparent, interconnected, electrically conductive network layer 14 can be applied by direct application onto a releasing substrate 18, 20, where it can be subsequently transferred to the OCA later 12 or OCA topcoat 16.

The interconnected, electrically conductive network layer 14 is applied at a thickness of between about 1 nm to about 1000 nm and particularly between about 100 and about 300 nm. When nanowires are used, the nanowire layer has a thickness of between about 10 and about 1000 nm.

### Releasing Substrates

The OCA layer 12 and topcoat 16 are contacted to releasing substrates 18 and 20, respectively, which may be any low adhesion substrate. The releasing substrates 18, 20 may be any suitable releasing substrate such as a release liner or a substrate containing a releasing surface. When adhered to an adhesive layer, releasing substrates adhere only lightly and are easily removed. A releasing substrate may be a single layer (with only the base layer) or it may be a multilayer construction (with one or more coatings or additional layers in addition to the base layer). The releasing substrate may also contain a structure such as a microstructure.

Suitable substrates containing a releasing surface include plates, sheets and film substrates. Examples of substrates containing a releasing surface include, for example, substrates that contain low surface energy surfaces such as TEFLON substrates, and polyolefin substrates such as polypropylene or polyethylene, or substrates which contain a release coating such as a silicone, olefinic, long alkyl chains or fluorochemical coating.

The OCA layer 12 and OCA topcoat 16 can be applied to films or sheeting products (e.g., optical, decorative, reflective, and graphical), labelstock, tape backings, release liners, and the like. The releasing substrates 18, 20 can be any suitable type of material depending on the desired application. In one embodiment, the releasing substrates 18, 20 are release liners. Exemplary release liners include those prepared from paper (e.g., Kraft paper) or polymeric material (e.g., polyolefins such as polyethylene or polypropylene, ethylene vinyl acetate, polyurethanes, polyesters such as polyethylene terephthalate, and the like). At least some release liners are coated with a layer of a release agent such as a silicone-containing material or a fluorocarbon-containing material. Exemplary release liners include, but are not limited to, liners commercially available from Eastman Chemicals Company (Kingsport, Tenn.) under the trade designation “T-30” and “T-10” that have a silicone release coating on polyethylene terephthalate film. The release liner can have a microstructure on its surface that is imparted to the adhesive to form a microstructure on the surface of the adhesive layer. The liner can then be removed to expose an adhesive layer having a microstructured surface.

The transparent, interconnected, electrically conductive network layer 14 can be coated onto a releasing substrate 18, 20 and subsequently transferred to an optical clear adhesive. If applied using this method, the releasing substrate 18, 20 must be able to survive process conditions for deposition of the transparent, interconnected, electrically conductive network layer 14. In some embodiments, fluorochemical-based releasing substrates can be used as a releasing substrate for metal coatings or conductive oxide coatings deposited by physical deposition method. In some embodiments, non-silicon liners may be desirable. Certain solution-based conductive layers can be solution coated onto the releasing substrates. In certain application, the releasing substrate can be coated or treated with an intermediate layer such as a thin coating used as a buffering layer for conductive layer fabrication. For example, if the particular the releasing substrate cannot survive metal deposition directly by a sputtering method, a thin acrylic layer can be coated onto the releasing substrate before metal deposition. Such buffering layer can also be a reinforcing layer or adhesive layer.

The transparent, interconnected, electrically conductive network layer on the releasing substrate can be further processed by, for example, etching, removing, or patterning for a particular electrical optical design purpose. In one embodiment, the transparent, interconnected, electrically conductive network layer can be printed onto a releasing substrate in a pre-defined pattern for a particular design or purpose. The releasing substrates can be also structured, microstructured, or patterned so that only a selected or random pattern can be transferred to the optically clear adhesive. Similarly, the optically clear adhesive can be structured, modified, or patterned so that the transparent, interconnected, electrically conductive network layer can only be transferred to a selected or random area of the optically clear adhesive.

### Electrically Conductive Ink Perimeter

An opaque electrically conductive ink perimeter 22 may optionally be applied as an image using a traditional printing process. FIG. 2 shows the COCA 10 with an opaque electrically conductive ink perimeter 22. In one embodiment, the opaque electrically conductive ink perimeter 22 is processed by screen printing the border with a conductive ink. The conductive ink may be made up of a binding resin, solvent and electrically conductive particles such as silver or carbon black. While silver and carbon black are specifically mentioned, any conductive particles may be used. In some embodiments, the conductive ink is opaque. An example of a commercially available ink includes, but is not limited to, AG-500 Conductive filled Silver ink available from Conductive Compounds Inc., Londonderry, N.H.

In one embodiment, the conductive ink is applied with a 60 durometer rubber squeegee on a 128 mesh PET screen with a blocked out polymer image on the screen to form the unprinted area. The ink is dried in air or at about 100° C. until the ink is tack-free. The conductive ink can be applied directly to the transparent, interconnected, electrically conductive network layer 14. If desired, the next layer of OCA adhesive can be isolated in the conductive tab area 24 by a piece of PET film similarly sized to the conductive tab area 24 of the electrically conductive ink perimeter 22, or by a releasing polymer such as polyvinyl alcohol or other polymer coating containing a releasing surface applied to the conductive tab area 24, allowing for easy separation of the conductive ink perimeter 22 from the OCA for purposes of electrical grounding. Examples of polymer coatings include, for example, substrates that contain low surface energy surfaces such as TEFLON substrates, and polyolefin substrates such as polypropylene or polyethylene, or substrates which contain a release coating such as a silicone, olefinic, long alkyl chains or fluorochemical coating. This results in a more effective EMI shield. Although FIG. 2 depicts the conductive ink perimeter 22 as being in registration with the transparent, interconnected, electrically conductive network layer 14, the conductive ink perimeter 22 can also overlap the transparent, interconnected, electrically conductive network layer 14 or be printed underneath the transparent, interconnected, electrically conductive network layer 14, as long as there is intimate contact. The conductive ink perimeter 22 has a surface resistivity of between about 0.1 and about 5 ohm/sq based on ink formula and ink thickness.

In one embodiment, the conductive ink perimeter has a thickness of between about 3 and about 25 microns, particularly between about 4 and about 10 microns, and more particularly about 6 microns.

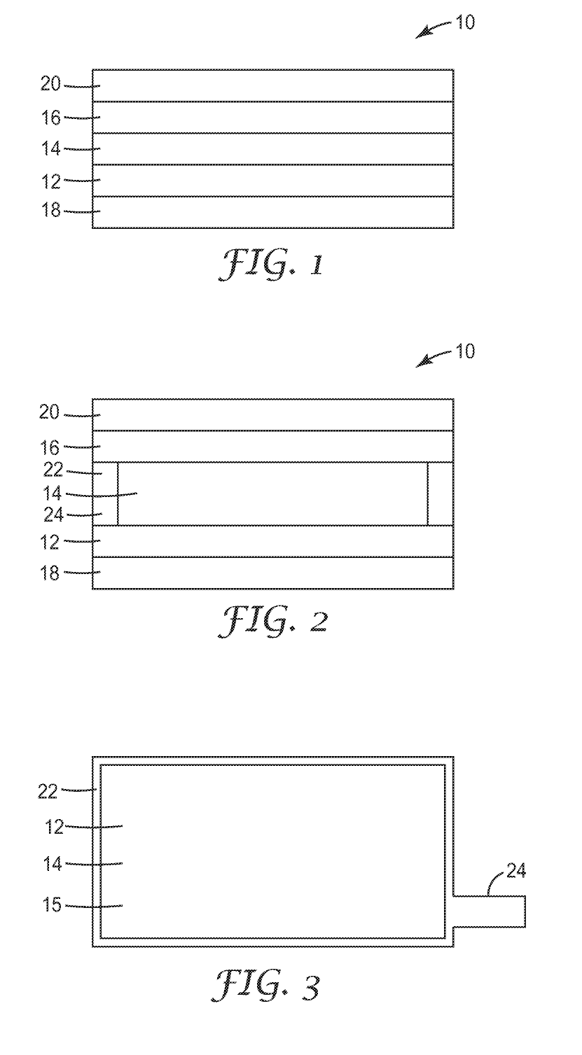

FIG. 3 shows an X/Y plane view of an electrically conductive ink perimeter 22 and a connection tab 24 of electrically conductive ink.

### Reinforcing Layer

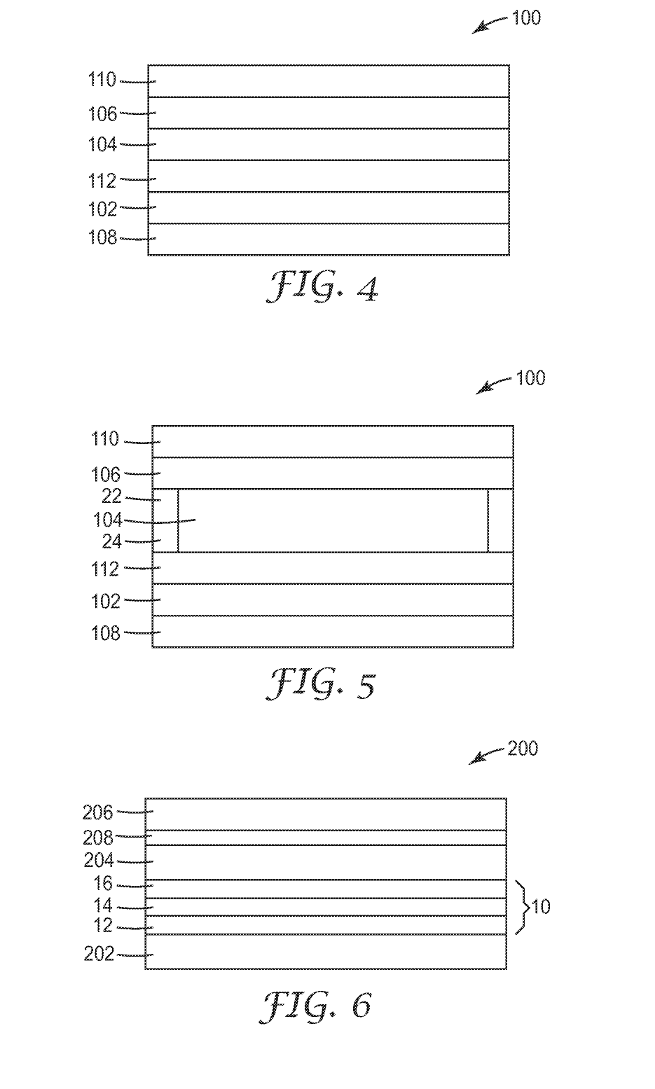

FIG. 4 shows a cross-sectional view of a second embodiment of an electrically conductive optically clear adhesive 100 of the present invention. The second embodiment of the electrically conductive OCA 100 is similar to the first embodiment of the electrically conductive OCA 10 and includes an interconnected, electrically conductive network layer 104 between an OCA layer 102 and an OCA topcoat 106. As with the first embodiment, the OCA topcoat 106 is optional. A first releasing substrate 108 and a second releasing substrate 110 are positioned adjacent the OCA layer 102 and the OCA topcoat 106, respectively.

The only difference between the first and second embodiments is that the second embodiment of the electrically conductive OCA 100 includes a reinforcing layer 112, such as an acrylic layer, positioned between the OCA layer 102 and the interconnected, electrically conductive network layer 104. The addition of the reinforcing layer 112 increases the stability of the electrically conductive OCA 100. In one embodiment, the reinforcing layer 112 has a thickness of between about 10 nm and about 250 microns.

The reinforcing layer 112 is intended to enhance certain properties depending on the particular desired design. The reinforcing layer 112 can increase the mechanical properties by, for example, increasing the flexibility endurance for the transparent, interconnected, electrically conductive network layer. In another embodiment, the reinforcing layer 112 can help the fabrication process for the transparent, interconnected, electrically conductive network layer, for certain processes, where the transparent, interconnected, electrically conductive network layer can lay down directly on the releasing substrate or optically clear adhesive. In another embodiment, the reinforcing layer 112 helps to enhance optical or electrical properties of the transparent, interconnected, electrically conductive network layer for a particular process, such as for example, ITO deposition on a hardcoat layer can be optically and electrically better than on a releasing substrate. Or, in certain processes, surface treatment on a supporting substrate is required before deposition of the transparent, interconnected, electrically conductive network layer, such as for example, corona treatment.

The reinforcing layer 112 can be part of the product or design (mechanical, optical, electrical, chemical). In one embodiment, the reinforcing layer 112 is a stretch reinforcing layer, such as a stretch release layer for a stretch release adhesive. In another embodiment, the reinforcing layer 12 is a polarizing layer, color layer, absorbing layer, or chemical absorbing layer. The reinforcing layer 112 may be composed of a polymer or inorganic layer. The reinforcing layer 112 may be continuous, non-continuous, a network, porous, non-porous, rigid, flexible, structured, patterned or non-patterned.

The reinforcing layer may also be a chemical barrier layer. For example, the COCA may be designed with two adhesives on either surface, one of which may not be chemically compatible with the other or the conductive material. The reinforcing layer can act as a chemical barrier between the two adhesives or between the adhesive and conductive layer. The reinforcing layer may be utilized to provide a robust and durable electrical connection to the conductive layer. For example, silver printing on a reinforcing layer made of polyester film can be utilized to contact the conductive layer in the COCA to provide increased reliable electrical connection where needed.

FIG. 5 shows the COCA 100 with an opaque electrically conductive ink perimeter 114. The opaque electrically conductive ink perimeter 114 functions similarly to the opaque electrically conductive ink perimeter 22 of the COCA 10. However, as shown in FIG. 5, the opaque electrically conductive ink perimeter 114 may be applied to the reinforcing layer 112.

Although FIGS. 1, 2, 4 and 5 depict the COCA 10, 100 as including an OCA layer 12, 102, an interconnected, electrically conductive network layer 14, 104 and an OCA topcoat 16, 106, various other configurations are contemplated without departing from the intended scope of the present invention. For example, in one embodiment, the COCA 10, 100 may include only an OCA layer 12, 102 and an interconnected, electrically conductive network layer 14, 104. In this embodiment, the COCA 10, 100 includes one surface that is capable of being electrically ground.

In another embodiment, a PET film may be positioned between the OCA layer and the interconnected, electrically conductive network layer. This configuration produces a double-sided adhesive with a reinforced conductive film.

Generally, a higher conductivity or lower surface resistivity or resistance of the electrically conductive optically clear adhesive 10, 100 is desired. In one embodiment, the electrically conductive optically clear adhesive 10, 100 has a surface resistivity of between about 0.5 and about 1000 ohm/square (ohm/sq), particularly between about 1 and about 500 ohm/sq more particularly between about 20 and about 200 ohm/sq and more particularly between about 30 and about 150 ohm/sq. The surface resistivity of the electrically conductive optically clear adhesive 10, 100 should remain relatively stable even after being exposed to increased humidity and temperature.

FIG. 6 is a cross-sectional view of the first embodiment of the electrically conductive optically clear adhesive 10 positioned within an electronic display 200. The electrically conductive optically clear adhesive 10 can be used in any article where an optically clear adhesive having electrical conductivity is desired. For example, the electrically conductive optically clear adhesive may be used in a touch sensor assembly or laminated to an anti-reflective film. When used in a touch sensor assembly, the electrically conductive optically clear adhesive is electrically grounded by, for example, a conductive gasket.

As can be seen in FIG. 6, a liquid crystal display (LCD) 202 is positioned adjacent the OCA layer 12 and a touch sensor 204 is positioned adjacent the OCA topcoat 16. A lense is laminated to the touch sensor 204 by an optically clear adhesive 208.

Because the network coating 14 is electrically conductive, it also functions as an electromagnetic interference (EMI) shield such that the COCA 10 has EMI shielding properties. Subsequently, there is no need for an EMI shielding layer, or an air gap, in any electronic display incorporating the COCA 10. Any resulting electronic display 200 incorporating the COCA 10 will thus be thinner than an electronic display that must include an EMI shielding layer or an air gap to prevent the LCD from interfering with the touch screen.

### Method of Manufacture

Each of the adhesive layers can be formed by either continuous or batch processes. An example of a batch process is the placement of a portion of the adhesive between a substrate to which the film or coating is to be adhered and a surface capable of releasing the adhesive film or coating to form a composite structure. The composite structure can then be compressed at a sufficient temperature and pressure to form an adhesive layer of a desired thickness after cooling. Alternatively, the adhesive can be compressed between two release surfaces and cooled to form an adhesive transfer tape useful in laminating applications.

Continuous forming methods include drawing the adhesive out of a film die and subsequently contacting the drawn adhesive to a moving plastic web or other suitable substrate. A related continuous method involves extruding the adhesive and a coextruded backing material from a film die and cooling the layered product to form an adhesive tape. Other continuous forming methods involve directly contacting the adhesive to a rapidly moving plastic web or other suitable preformed substrate. Using this method, the adhesive is applied to the moving preformed web using a die having flexible die lips, such as a rotary rod die. After forming by any of these continuous methods, the adhesive films or layers can be solidified by quenching using both direct methods (e.g., chill rolls or water baths) and indirect methods (e.g., air or gas impingement).

Adhesives can also be coated using a solvent-based method. For example, the adhesive can be coated by such methods as knife coating, roll coating, gravure coating, rod coating, curtain coating, die coating and air knife coating. The adhesive mixture may also be printed by known methods such as screen printing or inkjet printing. The coated solvent-based adhesive is then dried to remove the solvent. Typically, the coated solvent-based adhesive is subjected to elevated temperatures, such as those supplied by an oven, to expedite drying and/or curing of the adhesive.

In one embodiment, the OCA layer is first coated onto the first releasing substrate. In one embodiment, the OCA layer is coated using a die coating method or a slot fed knife coating method. The OCA layer is then dried and/or cured in three consecutive ovens. In one embodiment, the ovens are set at about 122° F., 176° F. and 230° F., respectively. In one embodiment, prior to wind-up, a second release liner can be laminated over the adhesive coating.

The interconnected, electrically conductive network layer is then coated over the OCA layer. The interconnected, electrically conductive network layer must be coated onto the OCA layer at a flow rate sufficient to enable enough network connections for the COCA to attain and maintain a certain conductivity or surface resistance. In one embodiment, the surface resistivity is between about 0.5 to about 1000 ohm/sq, particularly between about 1 and about 500 ohm/sq, more particularly between about 20 and about 200 ohm/sq and even more particularly between about 30 and about 150 ohm/sq. In one embodiment, the surface conductivity is maintained for at least about 72 hours in an environment of 65° C. and 90% relative humidity. Depending on material concentration, the flow rate may vary. In one embodiment, the interconnected, electrically conductive network layer is coated at a flow rate of at least about 20 cc/min, particularly at least about 32 cc/min and more particularly at least about 35 cc/min. In one embodiment, the interconnected, electrically conductive network layer is coated using a die coating method. In one embodiment, the interconnected, electrically conductive network layer is coated at a flow rate of between about 15 and about 45 cc/min, particularly between about 18 and about 42 cc/min, more particularly between about 20 and about 40 cc/min and even more particularly between about 30 and about 40 cc/min. If a second release liner is present, the second release liner over the OCA layer is removed from the stockroll just prior to coating the interconnected, electrically conductive network layer onto the OCA layer. The coating is then dried on-line through three consecutive ovens. In one embodiment, the ovens are set at about 122° F., 176° F. and 230° F., respectively. Prior to the wind-up, a releasing substrate may be laminated over the electrically conductive network layer.

An OCA topcoat layer is subsequently coated over the interconnected, electrically conductive network layer on the OCA layer after removing the releasing substrate, if present. In one embodiment, the OCA topcoat solution is coated using a die coating method from a pressure pot solution delivery system. Prior to coating, the coating solution is filtered. After coating, the topcoat is then dried on-line through three consecutive long ovens. In one embodiment, the ovens are set at about 122° F., 176° F. and 230° F., respectively. Prior to the wind-up, a releasing substrate may be laminated over the adhesive coating.

When an a reinforcing layer 112, e.g., an acrylic coating, is incorporated into the electrically conductive optically clear adhesive, the reinforcing layer may be coated onto the OCA layer prior to coating the reinforcing layer with the interconnected, electrically conductive network layer. In one embodiment, the reinforcing layer may be corona treated. The interconnected, electrically conductive network layer is then coated on the acrylic layer and the OCA topcoat layer is laminated.

In another embodiment, a sheet of interconnected, electrically conductive network layer previously coated on a reinforcing layer is laminated to an OCA topcoat layer such that the OCA is laminated to the exposed interconnected, electrically conductive network layer. The exposed surface of the reinforcing layer is then laminated with a second OCA layer, rendering a double coated electrically conductive optically clear adhesive. In one embodiment the reinforcing layer may be corona treated.

In some embodiments, the COCA is electrically connected. Depending on the design of the particular COCA, the COCA can feature an electrically conductive adhesive surface and electrical connection. For example, the COCA can be as simple as laminating a conductive surface of the COCA to a metal ground plane. Grounding or contact resistance can be improved if the metal surface is prepared free of any contamination. Stainless steel may not be a good surface condition due to native oxides, however, removal of oxides may help. Highly conductive surfaces such as gold plated or gold coated surfaces, or silver coated or silver ink printed surfaces may be considered. For other COCA design configurations, for example, when utilizing a reinforcing layer on which silver conductors are printed in contact with the conductive layer, an electrical connection to COCA can be made to the reinforcing layer. In some applications, grounding or electrical connection is not required.

### EXAMPLES

The present invention is more particularly described in the following examples that are intended as illustrations only, since numerous modifications and variations within the scope of the present invention will be apparent to those skilled in the art. Unless otherwise noted, all parts, percentages, and ratios reported in the following example are on a weight basis.

Materials

| Abbreviation or | |
|---|---|
| Trade Name | Description |
| Liner 1 | 1.5 mil silicone release liner available under the trade designation “ClearSIL |
| | Silicone Release Liner T-10” from Eastman Chemicals Company, Kingsport, |
| | TM |
| Liner 2 | A 1.5 mil release liner prepared as described in U.S. Pat. No. 7,816,477 |
| | (Suwa). |
| Adhesive Soln 1 | A 20.5% by weight OCA solution in a mixed solvent of methyl ethyl |
| | ketone/methanol/toluene/ethyl acetate (10/10/15/65 by weight). The OCA |
| | comprises a mixture of two copolymers, 90% by weight of a copolymer |
| | consisting of 93% isooctyl acrylate and 7% acrylic acid and 10% by weight |
| | of a copolymer consisting of 69% methyl methacrylate, 25% butyl |
| | methacrylate, and 6% dimethyl aminoethyl methacrylate. |
| Crosslinking | A 5% by weight solution of bisamide crosslinker (1,1′-isophthaloylbis(2- |
| Soln 1 | methylaziridne) in toluene. |
| ST475 | Silver nanowire dispersion available under the trade designation “ST475” |
| | from Seashell Technology, LLC, San Diego, California. |
| Ebecryl 8402 | An aliphatic polyurethane diacrylate available under the trade designation |
| | “EBECRYL 8402” available from Cytec Industries, Inc., Woodland Park, |
| | New Jersey. |
| SR833-S | Tricyclodecane Dimethanol Diacrylate available under the trade designation |
| | “SR833-S” from Sartomer USA, LLC, Exton, Pennsylvania. |
| Darocur 1173 | A photoinitiator, 2-hydroxy-2-methyl-1-phenyl-propan-1-one, available |
| | under the trade designation “DAROCUR 1173” from BASF, Ludwigshafen, |
| | Germany |
| S4 ClearOhm | A silver nanowire dispersion available under the trade designation “S4 Clear |
| | Ohm” from Cambrios Technologies Corp., Sunnyvale, California. |
| OCA 8172 | A 2 mil optically clear adhesive available under the trade designation |
| | “Optically Clear Adhesive 8172” from 3M Company, St. Paul, Minnesota. |
| OCA 8177 | A 7 mil optically clear adhesive available under the trade designation |
| | “Optically Clear Adhesive 8177” from 3M Company. |

### Test Methods

Sample preparation for Optical, Sheet Resistivity and Surface Resistance Measurements

A piece of conductive OCA with dual liners was cut to about 4 inch by 4 inch. After removing the appropriate release liners, the conductive OCA was hand laminated to a 2 inch (51 mm) by 3 inch (76 mm) glass slide (available under the trade designation Erie Scientific 2957F from VWR International, LLC, Radnor, Pa.), trimmed to the size of the glass, and laminated to a piece of PET film (available under the trade designation “TEIJIN TETORON HB3 PET”, from EI DuPont de Nemours & Co., Wilmington, Del.

### Optical Measurements

Total transmittance and transmission haze were measured with a Haze-Gard Plus Hazemeter (conforming to ASTM standard ASTM D 1003, D 1044) available from BYK-Gardner USA, Columbia, Md. Calibration was conducted with a zero transmission standard 4733, a 100% transmission of air, an 88.6% transmission standard HB4753 and a 76.2% clarity standard 4732.

Transmitted color (illuminant=CIE Yxy D65, 2 degree observers) was calculated using color application collecting data directly from Cary 100 UV-Vis Spectrophotometer available from Agilent Technologies, Santa Clara, Calif., with an external DRA-CA-3300 Diffuse Reflectance Accessory, Calibration with baseline correction of 100% transmission of air.

### Sheet Resistivity

Sheet resistivity, often called surface resistivity (the terms being used interchangeably in the present disclosure) was measured by an eddy current method using a Model 717B Benchtop Conductance Monitor available from Delcom Instruments, Inc., Prescott, Wis.

Samples were placed in a humidity oven at 85° C. and 85% relative humidity (RH) for three days. Sheet resistivity was recorded before and after the sample was exposed to this environmental condition.

### Surface Contact Resistance

Surface contact resistance of each conductive adhesive was measured using a comb pattern F from IPC multi-purpose test board, IPC-B-25A (P-IPC-B-25A with bare copper finish option), pattern F with 0.406 mm lines and 0.508 mm spaces, available from Diversified Systems, Inc., Indianapolis, Ind. The conductive OCA was cut into a 0.5 inch (1.3 cm) wide strip which was applied to pattern F using a hand-roller. Electrical resistance was measured between two contact pads of comb pattern F.

### Peel Force

A conductive OCA film sample was hand laminated, using a one inch rubber roller and hand pressure of about 0.35 kg/cm², to a 45 micron thick polyethylene terephthalate (PET) film. A 1 inch (25.4 cm) wide strip was cut from the adhesive film/PET laminate. This adhesive film side of the test strip was laminated, using a two kilogram rubber roller, to a stainless steel plate which had been cleaned by wiping it once with acetone and three times with heptane. The laminated test sample was allowed to remain at ambient conditions for one hour. The conductive OCA/PET laminate was removed from the stainless steel surface at an angle of 180 degrees at a rate of 30.5 cm/min. The force to peel the sample was measured with an Imass Model SP-2000 peel tester available from Imass Inc., Accord, Mass.

### Example 1

### Preparation of Optical Clear Adhesive Layer 1 (OCA-L1)

OCA-L1 was prepared by mixing 11 g of Crosslinking Soln 1 into 3,000 g of Adhesive Soln 1. The resulting solution was coated onto a 13 inch (33.0 cm) wide release liner, Liner 1, using a die coating method and apparatus as described in U.S. Pat. No. 5,759,274 (Maier et. al.) The line speed was 5 ft/min (1.5 m/min). The coating width of the solution was 11 inches (27.9 cm), giving a 1 inch (2.5 cm) uncoated margin on both sides of the coating. A gear pump solution delivery system was used to deliver the solution to the die at a solution flow rate of 185 cm³/min. The coated solution was dried in-line by running the liner with coating solution through a series of three, 2 meter long ovens having set temperatures of 122° F. (50° C.), 176° F. (80° C.) and 230° F. (110° C.), respectively. The coating thickness was estimated to be about 2 microns/. Prior to winding up the adhesive/Liner 1 into a roll, a second 13 inch (33.0 cm) wide release liner, Liner 1, was laminated to the exposed adhesive surface, forming OCA-L1 with dual release liners.

### Preparation of Silver Nanowire Dispersion 1 (SNW-D1)

SNW-D1 was prepared as follows. 700.0 grams of deionized water, 0.609 g of hydroxypropyl methyl cellulose (available from Sigma-Aldrich, St. Louis, Mo.) and 0.038 grams of Zonyl FSO-100 fluorosurfactant (available from Sigma-Aldrich) were placed in a 1000 mL Erlenmeyer flask. The solution was heated to boiling with magnetic stirring, and then left to cool overnight while stirring. A clear solution was formed. The clear solution was filtered through a 5 micron syringe filter. 46.31 grams of ST475 was placed in a second 1000 mL Erlenmeyer flask. Next, 527.4 grams of the clear solution from the first Erlenmeyer flask was added to the ST475 in the second Erlenmeyer flask. The resulting grey dispersion was magnetically stirred for 3 hours, and then degassed using a rotary evaporator producing SNW-D1.

### Preparation of OCA-L1 with Silver Nanowire Coating 1 (SNW-C1)

SNW-D1 was coated over OCA-L1 using a continuous process. Just prior to coating, one of the release liners of the previously prepared OCA-L1 with dual release liners was removed from the surface of OCA-L1. SNW-D1 was die coated on OCA-L1 using a die coating method and apparatus as described in U.S. Pat. No. 5,759,274 (Maier et. al.). The line speed was a 20 ft/min (6.1 m/min). The coating width was 11 inches (27.9 cm) and corresponded to the previous OCA-L1 coating width, giving a 1 inch (2.5 cm) uncoated margin on both sides of the coating. A syringe pump was used to deliver the SNW-D1 to the coating die at a flow rate of 32 cm³/min. The SNW-D1 coating was dried in-line by running the liner with OCA-L1 and SNW-D1 coating solution through a series of three, 2 meter long ovens having set temperatures of 122° F. (50° C.), 176° F. (80° C.) and 230° F. (110° C.), respectively. Prior to winding up the construction, a second 13 inch (33.0 cm) wide release liner, Liner 1, was laminated to the exposed surface of the silver nanowire coating, forming OCA-L1 with SNW-C1 having dual liners.

### Preparation of OCA-L1 with Silver Nanowire Coating 1 (SNW-C1) and Optical Clear Adhesive Layer 2 (OCA-L2)

OCA-L2 was subsequently coated over the silver nanowire coating of the above described OCA-L1 with SNW-C1 having dual liners. A 4% by weight solution of OCA was prepared by diluting 488 g of Adhesive Soln 1 with 2,500 g with ethyl acetate. Next, 1.8 grams of Crosslinking Soln 1 was added to the OCA solution. Just prior to coating, the release liner adjacent to SNW-C1 was removed. The OCA topcoat solution was coated on SNW-C1 using a die coating method and apparatus as described in U.S. Pat. No. 5,759,274 (Maier et. al.). The line speed was 10 ft/min (3.05 m/min). A pressure pot solution delivery system was used to deliver the OCA solution to the die at a flow rate of 30 g/min. Prior to coating, the OCA topcoat solution was filtered using an in-line, 1 micron filter. The coating width was 11 inches (27.9 cm) and corresponded to the previous SNW-C1 width, giving a 1 inch (2.5 cm) uncoated margin on both sides of the coating. The OCA topcoat solution was dried in-line by running the liner with OCA-L1, SNW-C1 and OCA topcoat solution through a series of three, 2 meter long ovens having set temperatures of 122° F. (50° C.), 176° F. (80° C.) and 230° F. (110° C.), respectively. The coating thickness was estimated to be about 1 micron or less. Prior to winding up the construction, a second 13 inch (33.0 cm) wide release liner, Liner 1, was laminated to the exposed adhesive surface of OCA-L2, forming a conductive OCA having OCA-L1 with SNW-C1 and OCA-L2, Example 1, with dual release liners.

### Example 2

Example 2 was prepared as described in Example 1 except SNW-D1 was coated onto OCA-L1 at a solution flow rate of 34 cm³/min.

### Example 3

Example 3 was prepared as described in Example 1, except SNW-D1 was coated onto OCA-L1 at a solution flow rate of 36 cm³/min.

### Example 4

Example 4 was prepared as described in Example 1, except SNW-D1 was coated onto OCA-L1 at a solution flow rate of 40 cm³/min.

### Example 5

Example 5 was prepared as described for Example 1, except the nanowire dispersion was changed from SNW-D1 to SNW-D2 which yielded Silver Nanowire Coating 2 (SNW-C2), after coating and drying of the silver nanowire dispersion. SNW-D2 was prepared by adding 105 ml isopropanol to 2,000 ml of ClearOhm ink, yielding about a 5% by volume silver nanowire dispersion. The resulting dispersion was then degassed on a rotary evaporator at reduced pressure for about 50 minutes. SNW-D2 was die coated over OCA-L1 using a die coating method and apparatus as described in U.S. Pat. No. 5,759,274 (Maier et. al.). The line speed was a 20 ft/min (6.1 m/min). A syringe pump was used to deliver the SNW-D2 to the coating die at a flow rate of 26 cm³/min.

### Example 6

### Preparation of Optical Clear Adhesive Layer 2 (OCA-L3)

Adhesive Soln 1 was diluted to 5.5% by weight adhesive by adding ethyl acetate. To 1,500 g of this diluted adhesive solution was added 2 g of Crosslinking Soln 1. The resulting solution was coated onto a 13 inch (33.0 cm) wide release liner, Liner 2, using a die coating method and apparatus as described in U.S. Pat. No. 5,759,274 (Maier et. al.). The line speed was 10 ft/min (3.05 m/min). The coating width of the solution was 11 inches (27.9 cm), giving a 1 inch (2.5 cm) uncoated margin on both sides of the coating. A pressure pot solution delivery system was used to deliver the solution to the die at a rate of 15 g/min. The coated solution was dried in-line by running the liner with coating solution through a series of three, 2 meter long ovens having set temperatures of 122° F. (50° C.), 176° F. (80° C.) and 230° F. (110° C.), respectively. The coating thickness was estimated to be less than 1 micron. Prior to winding up the adhesive/Liner 2 into a roll, a second 13 inch (33.0 cm) wide release liner, Liner 1, was laminated to the exposed adhesive surface, forming OCA-L3 with dual release liners.

### Preparation of Silver Nanowire Dispersion 2 (SNW-D2)

SNW-D2 was prepared as described in Example 5.

### Preparation of OCA-L3 with Silver Nanowire Coating 3 (SNW-C3)

SNW-D2 was coated over OCA-L3 using a continuous process. Just prior to coating, one of the release liners, Liner 1, of the previously prepared OCA-L3 with dual release liners was removed from the surface of OCA-L3. SNW-D2 was die coated on OCA-L3 using a die coating method and apparatus as described in U.S. Pat. No. 5,759,274 (Maier et. al.). The line speed was a 20 ft/min (6.1 m/min). The coating width was 11 inches (27.9 cm) and corresponded to the previous OCA-L2 coating width, giving a 1 inch (2.5 cm) uncoated margin on both sides of the coating. A syringe pump was used to deliver the SNW-D2 to the coating die at a flow rate of 20 cm³/min. The SNW-D2 coating was dried in-line by running the liner with OCA-L3 and SNW-D2 coating solution through a series of three, 2 meter long ovens having set temperatures of 122° F. (50° C.), 176° F. (80° C.) and 230° F. (110° C.), respectively. Prior to winding up the construction, a second 13 inch (33.0 cm) wide release liner, Liner 1, was laminated to the exposed surface of the silver nanowire coating, forming OCA-L3 with SNW-C3 having dual liners.

### Preparation of OCA-L3 with Silver Nanowire Coating 3 (SNW-C3) and Optical Clear Adhesive Layer 4 (OCA-L4)

OCA-L4 was subsequently laminated over the silver nanowire coating of the above described OCA-L3 with SNW-C3 having dual liners. A sheet of OCA 8172 was laminated to SNW-2 using roll-to-roll laminator at line speed of 5.8 ft/min (1.77 m/min) at a laminating pressure of 30 psi. During the lamination process, the release liner over the silver nanowires layer and one of the release liners of OCA 8172 were removed. The lamination process produced a conductive OCA having OCA-L3 with SNW-C3 and OCA-L4, Example 6, with dual release liners.

### Example 7

Example 7 was prepared as described in Example 6 except SNW-D2 was coated onto OCA-L3 at a solution flow rate of 24 cm³/min.

### Example 8

Example 8 was prepared as described in Example 6, except SNW-D2 was coated onto OCA-L3 at a solution flow rate of 28 cm³/min.

### Example 9

Example 9 was prepared as described in Example 6, except SNW-D2 was coated onto OCA-L3 at a solution flow rate of 32 cm³/min.

### Example 10

Example 10 was prepared as described in Example 6, except SNW-D2 was coated onto OCA-L3 at a solution flow rate of 40 cm³/min.

### Example 11

### Preparation of Acrylic Coating Layer 1 (AC-L1)

AC-L1 was prepared by mixing 84.5 wt. % Ebecryl 8402, 11.5 wt. % SR833-S and 4.0 wt. % Darocur 1173. The resulting 100% solids mixture was coated onto a 13 inch (33.0 cm) wide release liner, Liner 2, using a slot fed knife coating method with the die heated at 50° C. The line speed was 10 ft/min (3.05 m/min). The coating width of the mixture was 11 inches (27.9 cm), giving a 1 inch (2.5 cm) uncoated margin on both sides of the coating. A pressure pot solution delivery system was used. The coating was UV cured in-line using a Coolwave UV curing system (available from Nordson Corporation, Westlake, Ohio) containing an H-bulb (part #775042A-H, available from Primarc UV technology, Berkshire, U.K), at 100% power with dichroic reflectors and a nitrogen gas purge. The Coolwave UV curing system was contained in an apparatus that allowed for nitrogen gas purging during the curing process. A back-up roll was used during the curing process set at a temperature of 70° F. (21° C.), yielding AC-L1. The final cured coating thickness was 30 microns. After curing, it was noted that the cured coating was easily removed from the release liner.

### Preparation of Silver Nanowire Dispersion 1 (SNW-D1)

The silver nanowire dispersion, SNW-D1 was prepared as described in Example 1.

### Preparation of AC-L1 with Silver Nanowire Coating 1 (SNW-C1)

AC-L1 was corona treated under nitrogen at 500 J/cm² using standard techniques, prior to coating with SNW-D1. SNW-D1 was coated onto AC-L1 using the procedures and conditions described in Example 1. SNW-D1 was coated over acrylic coating side of AC-L1 using a continuous process. SNW-D1 was coated using a die coating method and apparatus as described in U.S. Pat. No. 5,759,274 (Maier et. al.). The line speed was a 20 ft/min (6.1 m/min). The coating width was 11 inches (27.9 cm). A syringe pump was used to deliver the SNW-D1 to the coating die at a flow rate of 32 cm³/min. The SNW-D1 coating was dried in-line through a series of three, 2 meter long ovens having set temperatures of 122° F. (50° C.), 176° F. (80° C.) and 230° F. (110° C.), respectively.

### Preparation of AC-L1 with Silver Nanowire Coating 1 (SNW-C1) and Optical Clear Adhesive Layer 4 (OCA-L4) and Optical Clear Adhesive Layer 5 (OCA-L5)

A sheet about 6 inch (15.2 cm) by 10 inch (25.4 cm) of AC-L1 with SNW-C1 was laminated to a sheet of OCA 8172 using a hand lamination techniques with a rubber roller The OCA 8172 was laminated to the SNW-C1, after removing one of the release liners from the OCA 8172. Next, the release liner was the removed from AC-L1 of the AC-L1/SNW-C1/OA 8172 multilayer construction. After removing a release liner from a sheet of OCA 8177, OCA 8177 was hand laminated to AC-L1, forming a conductive OCA having AC-L1 with Silver Nanowire Coating 1 (SNW-C1) and OCA-L4 (OCA 8172) and OCA-L5 (OCA 8177), Example 11, with dual release liners.

### Example 12

Example 12 was prepared as described in Example 11, except SNW-D1 was coated onto AC-L1 at a dispersion flow rate of 36 cm³/min.

### Comparative Example A

Comparative Example A is OCA 8172, as received.

Table 1 below lists the surface resistivity, surface resistivity after exposure to heightened temperature and humidity, transmission, haze, surface contact resistance, transmitted color, and peel strength of Examples 1-12 and Comparative Example A.

TABLE 1

| | | Surface | | | | | | | |
|---|---|---|---|---|---|---|---|---|---|
| | | Resistivity | | | | | | | |
| | | after | | | Surface | | | | |
| | Surface | 85° C./85 | | | Contact | | | | Peel |
| | Resistivity | RH | Trans. | Haze | Resistance | Transmitted Color | | | Strength |
| Example | (ohm/sq) | (ohm/sq) | (%) | (%) | (ohm) | Y | x | y | (oz/inch) |
| 1 | 452 | 232 | 85.7 | 5.25 | 190 | 84.6 | 0.3145 | 0.3314 | 41.4 |
| 2 | 183 | 157 | 85.5 | 5.55 | 54 | 84.3 | 0.3145 | 0.3314 | 40.8 |
| 3 | 93 | 87 | 85 | 6.21 | 19 | 83.9 | 0.3146 | 0.3315 | 34.4 |
| 4 | 59 | 49 | 84.5 | 7.01 | 17 | 83.4 | 0.3147 | 0.3316 | 33.8 |
| 5 | 116 | 98* | 88.7 | 1.22 | — | — | — | — | — |
| 6 | 1250 | 714 | 89.3 | 1 | 5,000 | 88.5 | 0.3140 | 0.3311 | 38.9 |
| 7 | 212 | 192 | 89.1 | 1.14 | 740 | 88.1 | 0.3141 | 0.3313 | 35.7 |
| 8 | 135 | 147 | 88.9 | 1.35 | 850 | 87.9 | 0.3142 | 0.3315 | 38.6 |
| 9 | 102 | 115 | 88.5 | 1.38 | 450 | 87.6 | 0.3145 | 0.3318 | 44.9 |
| 10 | 76 | 94 | 88.2 | 1.58 | 250 | 87.2 | 0.3148 | 0.3320 | 43.8 |
| 11 | 121 | 89 | 85.8 | 5.65 | — | 84.6 | .03146 | 0.3316 | 37.2 |
| 12 | 65 | 66 | 85.2 | 6.48 | — | 83.6 | 0.3147 | 0.3317 | 38.4 |
| A | — | — | 90.2 | 0.41 | — | 89.2 | 0.3136 | 0.3303 | 36.4 |

*Environmental testing was conducted at 85° C. and 85% relative humidity for seven days.

Although the present invention has been described with reference to preferred embodiments, workers skilled in the art will recognize that changes may be made in form and detail without departing from the spirit and scope of the invention.

1. An electrically conductive, optically clear adhesive comprising:
an optically clear adhesive layer; and
an interconnected, electrically conductive network layer positioned over the optically clear adhesive layer;
wherein the electrically conductive, optically clear adhesive has a surface resistivity of between about 0.5 and about 1000 ohm/sq, haze of less than about 10%, and a transmittance of at least about 80%.

2. The electrically conductive, optically clear adhesive of claim 1, wherein the interconnected, electrically conductive network layer comprises nanowires.

3. The electrically conductive, optically clear adhesive of claim 1, wherein the interconnected, electrically conductive network layer comprises a non-continuous conductive layer.

4. The electrically conductive, optically clear adhesive of claim 1, wherein the interconnected, electrically conductive network layer comprises a conductive pattern.

5. The electrically conductive, optically clear adhesive of claim 1, wherein the interconnected, electrically conductive network layer comprises conductive mesh.

6. The electrically conductive, optically clear adhesive of claim 2, wherein the nanowires are silver.

7. The electrically conductive, optically clear adhesive of claim 1, further comprising an optically clear adhesive layer topcoat positioned over the interconnected, electrically conductive network layer.

8. The electrically conductive, optically clear adhesive of claim 1, further comprising a reinforcing layer positioned between the optically clear adhesive layer and the interconnected, electrically conductive network layer.

9. The electrically conductive, optically clear adhesive of claim 1, having a surface resistivity of between about 20 and about 200 ohm/sq.

10. The electrically conductive, optically clear adhesive of claim 9, having a surface resistivity of between about 30 and about 150 ohm/sq.

11. The electrically conductive, optically clear adhesive of claim 1, having a haze of less than about 5%.

12. The electrically conductive, optically clear adhesive of claim 11, having a haze of less than about 2%.

13. The electrically conductive, optically clear adhesive of claim 1, having a transmittance of greater than about 85%.

14. The electrically conductive, optically clear adhesive of claim 13, having a transmittance of greater than about 88%.

15. The electrically conductive, optically clear adhesive of claim 1, wherein the electrically conductive, optically clear adhesive is a transparent electrical conductor.

16. The electrically conductive, optically clear adhesive of claim 1, wherein the interconnected, electrically conductive network layer can be electrically grounded to a ground plane.

17. An electrically conductive, optically clear adhesive comprising:
an optically clear adhesive layer;
a conductive nanowire network layer positioned over the optically clear adhesive layer, wherein the conductive nanowire network layer helps control electromagnetic interference; and
an optically clear adhesive layer topcoat positioned over the conductive nanowire network layer.

18. The electrically conductive, optically clear adhesive of claim 17, having a thickness of less than about 20 mil.

19. The electrically conductive, optically clear adhesive of claim 17, wherein the adhesive is birefringence-free.

20. The electrically conductive, optically clear adhesive of claim 17, wherein the optically clear adhesive layer is a pressure-sensitive adhesive.
